(19) United States
(12) Patent Application Publication
(10) Pub. No.: US 2008/0128790 A1
(43) Pub. Date: Jun. 5, 2008

(54) MEMORY DEVICE

(76) Inventor: Jin-Hyo Jung, Gyeongi-do (KR)

Correspondence Address: SHERR & NOURSE, PLLC, 620 HERNDON PARKWAY, SUITE 200, HERNDON, VA, 20170, US

(21) Appl. No.: 11/869,461

(22) Filed: Oct. 9, 2007

(30) Foreign Application Priority Data
Nov. 30, 2006 (KR) 10-2006-0119468

(51) Int. Cl. H01L 29/792

(52) U.S. Cl. 257/325; 257/E29.309

(57) ABSTRACT

A memory device including a region doped with first conductive impurities; a first polysilicon layer doped with second conductive impurities and formed on the region doped with first conductive impurities; a second polysilicon layer formed on the first polysilicon layer and doped with first conductive impurities; an electric charge capture layer formed at a lateral side of the first polysilicon layer; and a control gate formed at a lateral side of the electric charge capture layer.

The present application claims priority under 35 U.S.C. 119 and 35 U.S.C. 365 to Korean Patent Application No. 10-2006-0119468 (filed on Nov. 30, 2006), which is hereby incorporated by reference in its entirety.

### BACKGROUND

A flash memory device has the advantages of EPROM with programming and erasing characteristics and EEPROM having electrically programming and erasing characteristics. The flash memory device is capable of storing 1 bit of data and perform both electrical programming and erasing operations.

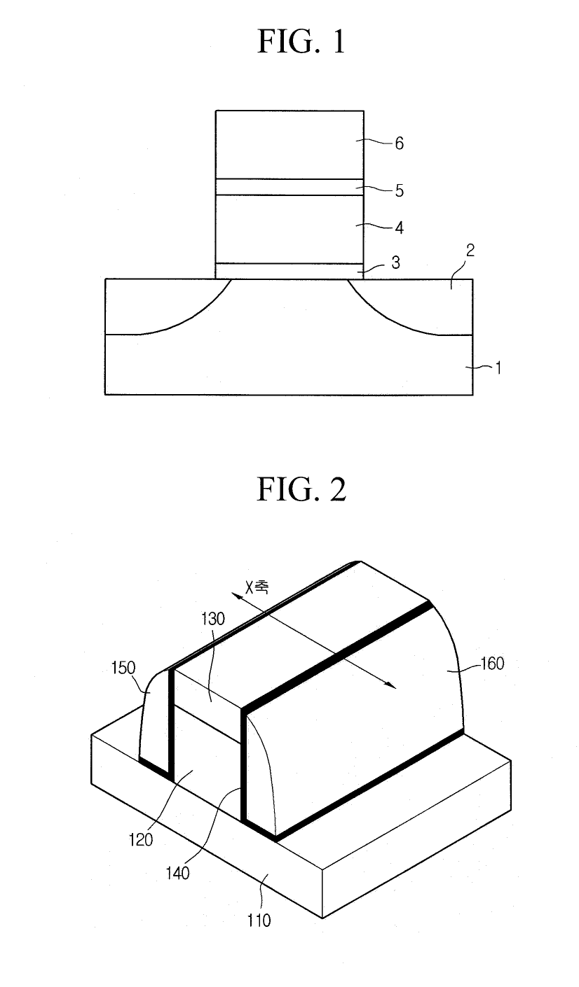

As illustrated in example FIG. 1, a flash memory device may include thin tunnel oxide layer 3 formed on and/or over silicon semiconductor substrate 1, floating gate 4 formed on and/or over tunnel oxide layer 3, insulating layer 5 formed on and/or over floating gate 4, control gate 6 formed on and/or over insulating layer 5, and source/drain area 2 formed on and/or over silicon semiconductor substrate 1.

### SUMMARY

Embodiments relate to a memory device including: a region doped with first conductive impurities; a first polysilicon layer doped with second conductive impurities and formed on and/or over the region doped with first conductive impurities; a second polysilicon layer formed on and/or over the first polysilicon layer and doped with first conductive impurities; an electric charge capture layer formed at a lateral side of the first polysilicon layer; and a control gate formed at a lateral side of the electric charge capture layer.

Embodiments relate to a memory device including: a region doped with first conductive impurities; a first polysilicon layer doped with second conductive impurities and formed on and/or over the region doped with first conductive impurities; a second polysilicon layer formed on and/or over the first polysilicon layer and doped with first conductive impurities; an electric charge capture layer formed at both lateral sides of the first polysilicon layer; and first and second control gates formed at lateral sides of the electric charge capture layer.

Embodiments relate to a memory device including: source and drain regions formed in a semiconductor substrate; a channel region formed between the source and drain regions; an electric charge capture layer adjacent to the channel region; and a control gate adjacent to the electric charge capture layer, wherein the source region, the channel region and the drain region are vertically aligned, and the channel region, the electric charge capture layer and the control gate are horizontally aligned.

Embodiments relate to a memory device including: a source region, a common channel region and a drain region formed in a semiconductor substrate, wherein the source region, the common channel region and the drain region are aligned in a first direction; a plurality of electric charge capture layers that capture electric charges in the common channel region; and a plurality of control gates to which control voltage is applied.

### DRAWINGS

Example FIG. 1 illustrates a flash memory device.

Example FIGS. 2 to 9 illustrate a flash memory device, in accordance with embodiments.

### DESCRIPTION

In the following description of the embodiments, when it is described that layers (films), regions, patterns or structures are formed “on/above/over/upper” or “down/below/under/lower” layers (films), regions, patterns or structures, it means that they directly make contact with the layers (films), regions, patterns or structures, or they indirectly make contact with the layers (films), regions, patterns or structures by interposing other layers (films), regions, patterns or structures therebetween. Thus, the meaning must be determined based on the scope of the present invention.

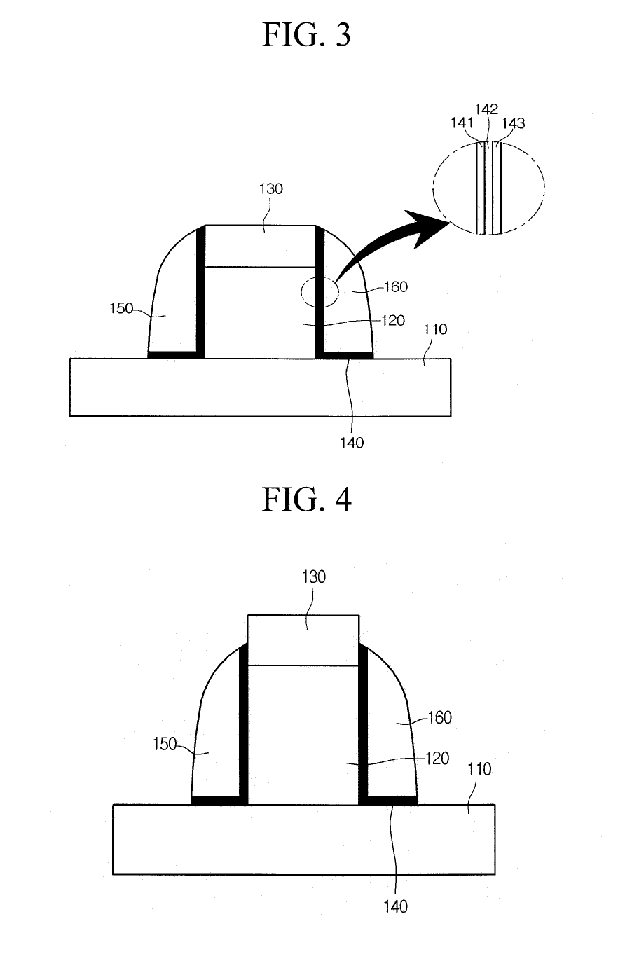

As illustrated in example FIGS. 2 and 3, the flash memory device in accordance with embodiments can include a semiconductor substrate on which region 110 doped with first conductive impurities is formed. The first conductive impurities may include N-type impurities, such as phosphorous (P) or arsenic (As), or P-type impurities, such as boron (B). According to the embodiment, the first conductive impurities include N-type impurities. In addition, the semiconductor substrate can be doped with N-type impurities.

First polysilicon layer 120 can be formed on and/or over region 110 doped with the first conductive impurities. First polysilicon layer 120 can be doped with second conductive impurities different from the first conductive impurities. If the first conductive impurities are N-type impurities, the second conductive impurities are P-type impurities, so first polysilicon layer 120 forms a P-well.

Second polysilicon layer 130 can be formed on and/or over first polysilicon layer 120. Second polysilicon layer 130 can be doped with the first conductive impurities.

Therefore, region 110 doped with the first conductive impurities, first polysilicon layer 120 and second polysilicon layer 130 may form a vertical stack structure which is sequentially doped with N-type impurity/P-type impurity/N-type impurity.

Electric charge capture layer 140 can be formed laterally at both sides of first polysilicon layer 120 and second polysilicon layer 130. Electric charge capture layer 140 may include an insulating layer. As illustrated in example FIG. 3, in accordance with embodiments, electric charge capture layer 140 may include an ONO layer in which first oxide layer 141, nitride layer 142 and second oxide layer 143 are sequentially deposited. Electric charge capture layer 140 having an ONO layer may include one selected from the group consisting of SiO₂—Si₃N₄—SiO₂, SiO₂—Si₃N₄—Al₂O₃, SiO₂—Si₃N₄—Al₂O₃, and SiO₂—Si₃N₄—SiO₂—Si₃N₄—SiO₂.

First control gate 150 and second control gate 160 including polysilicon can be formed on and/or over electric charge capture layer 140. In detail, first control gate 150 and second control gate 160 can be formed on and/or over region 110 doped with the first conductive impurities and laterally at both sides of first polysilicon layer 120 and second polysilicon layer 130.

As illustrated in example FIG. 4, a flash memory device in accordance with embodiments may include second polysilicon layer 130 formed higher than first control gate 150 and second control gate 160.

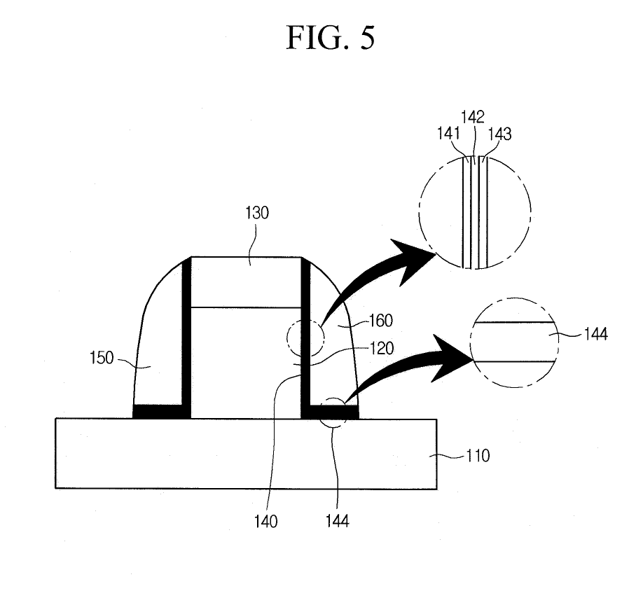

As illustrated in example FIG. 5, a flash memory device in accordance with embodiments may include electric charge capture layer 140 formed at the lateral side of the first polysilicon layer 120 and second polysilicon layer 130. Electric charge capture layer may be formed having ONO structure by sequentially depositing first oxide layer 141, nitride layer 142 and second oxide layer 143. Electric charge capture layer 140 having a ONO structure may include one selected from the group consisting of SiO₂—Si₃N₄—SiO₂, SiO₂—Si₃N₄—Al₂O₃, SiO₂—Si₃N₄—Al₂O₃, and SiO₂—Si₃N₄—SiO₂—Si₃N₄—SiO₂.

In addition, insulating layer 144 having a structure different from that of the ONO layer of electric charge capture layer 140 can be formed between the first control gate 150 and second control gate 160 and region 110 doped with the first conductive impurities.

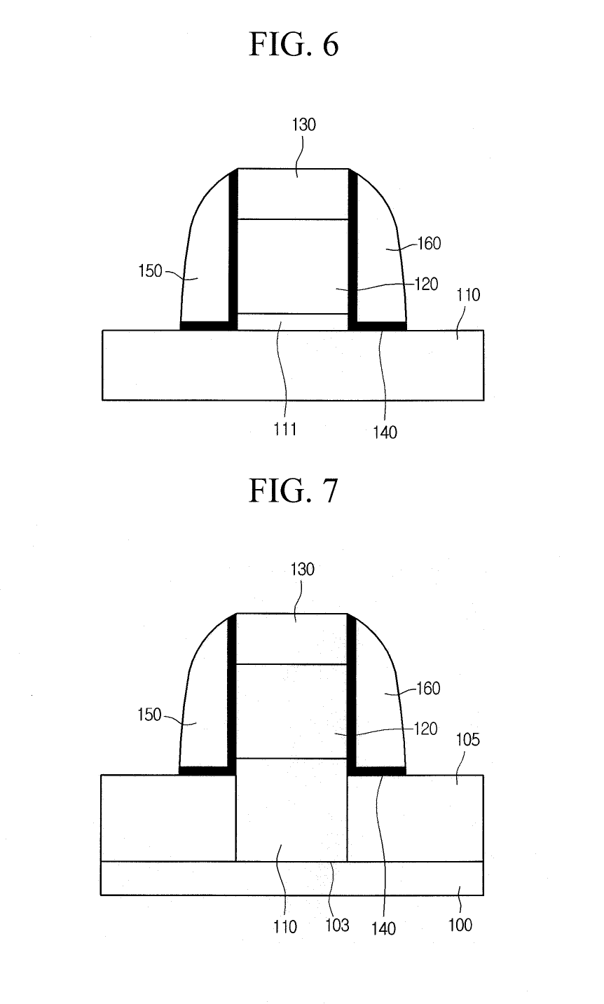

As illustrated in example FIG. 6, a flash memory device in accordance with embodiments may include protrusion 111 which protrudes from a predetermined portion of region 110 doped with the first conductive impurities. First polysilicon layer 120 can be formed on and/or over protrusion 111. Protrusion 111 may include a material identical to the material of region 110 doped with the first conductive impurities.

As illustrated in example FIG. 7, a flash memory device in accordance with embodiments may include insulating layer 105 formed on and/or over semiconductor substrate 100 and includes trench 103. Region 110 doped with the first conductive impurities can be formed in trench 103.

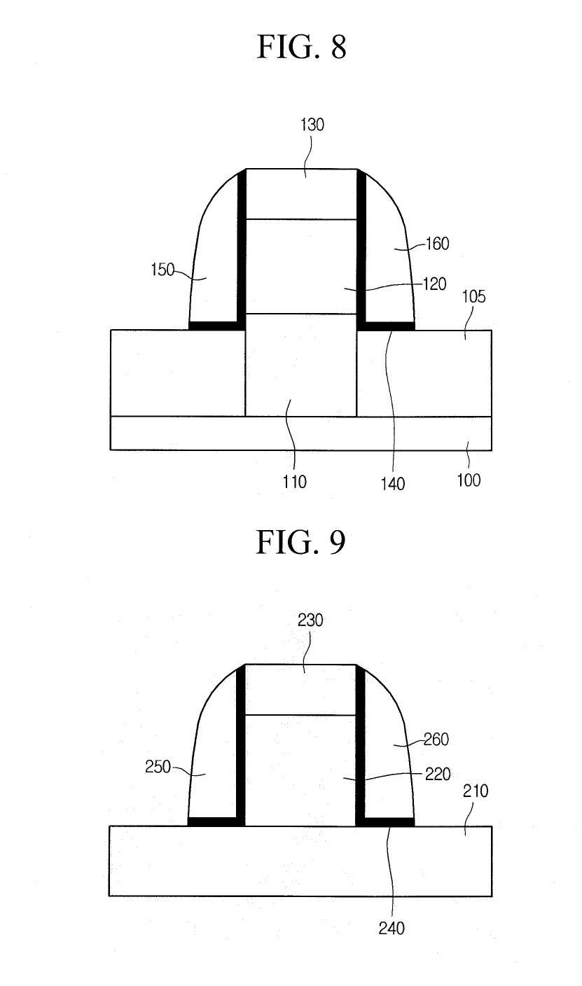

As illustrated in example FIG. 8, a flash memory device in accordance with embodiments may include semiconductor substrate 100, which is a P-type semiconductor substrate. Region 110 doped with the first conductive impurities can be formed on and/or over a predetermined area of P-type semiconductor substrate 100 as an N-type polysilicon layer. In addition, insulating layer 105 can be formed at both lateral sides of region 110 doped with the first conductive impurities.

As illustrated in example FIG. 9, a flash memory device in accordance with embodiments may include region 210 doped with second impurities and including P-type polysilicon. First polysilicon layer 220, which is doped with N-type impurities to form an N-well, and second polysilicon layer 230 doped with P-type impurities can be formed on and/or over region 210 doped with second impurities. Electric charge capture layer 240 can be formed at both lateral sides of first polysilicon layer 220 and second polysilicon layer 230. First control gate 250 and second control gate 260 including polysilicon can be formed on and/or over electric charge capture layer 240.

In accordance with embodiments, a flash memory device including region 110 doped with the first impurities and region 210 doped with the second impurities may form a source/drain area having a vertical structure in cooperation with second polysilicon layer 130 and 230. Moreover, first polysilicon layer 120, which is doped with P-type impurities to form a P-well, and first polysilicon layer 220 doped with N-type impurities to form an N-well, may serve as a channel which is a path for electric charges (or holes).

Electric charge capture layer 140, which can be formed having a ONO layer including first oxide layer 141, nitride layer 142 and second oxide layer 143 that are sequentially deposited, the electric charges can be programmed or erased at nitride layer 142, first oxide layer 141 can serve as a tunneling oxide layer to guide the electric charges from a channel to nitride layer 142, and second oxide layer 143 can serve as a blocking oxide layer that prevents the electric charges from moving from nitride layer 142 to first control gate 150 and second control gate 160.

Meaning, as voltage is applied to first control gate 150, the electric charges (or holes) are discharged from region 110 which is doped with the first impurities and serves as a source, and the discharged electric charges can be programmed in nitride layer 142 of electric charge capture layer 140. Then, if the voltage being applied to first control gate 150 is shut off, the electric charges (or holes) programmed in nitride layer 142 can be erased.

In the same manner, as the voltage is applied to second control gate 160, the electric charges (or holes) are discharged from region 110 which is doped with the first impurities and serves as a source, and the discharged electric charges can be programmed in nitride layer 142 of electric charge capture layer 140. Then, if the voltage being applied to second control gate 160 is shut off, the electric charges (or holes) programmed in nitride layer 142 can be erased.

Therefore, in accordance with embodiments, the electric charge capture layer is provided at both sides of the channel formed between the source and the drain having the vertical structure, so the flash memory device can store data of 2 bits without increasing the size of the flash memory device. In addition, if the flash memory device is combined with a multi-level bit technology, one cell can store four bits to eight bits.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a region doped with first conductive impurities;
a first polysilicon layer doped with second conductive impurities and formed over the region doped with first conductive impurities;
a second polysilicon layer formed over the first polysilicon layer and doped with first conductive impurities;
an electric charge capture layer formed at a lateral side of the first polysilicon layer; and
a control gate formed at a lateral side of the electric charge capture layer.

2. The apparatus of claim 1, wherein the electric charge capture layer comprises a first oxide layer, a nitride layer, and a second oxide layer.

3. The apparatus of claim 1, wherein the electric charge capture layer comprises one selected from the group consisting of SiO₂—Si₃N₄—SiO₂, SiO₂—Si₃N₄—Al₂O₃, SiO₂—Si₃N₄—Al₂O₃, and SiO₂—Si₃N₄—SiO₂—Si₃N₄—SiO₂.

4. The apparatus of claim 1, wherein the second polysilicon layer protrudes beyond the control gate.

5. The apparatus of claim 1, further comprising a protrusion formed over the region doped with the first conductive impurities, and the first polysilicon layer is formed over the protrusion.

6. The apparatus of claim 1, further comprising an insulating layer formed at both sides of the region doped with the first conductive impurities.

7. An apparatus comprising:
a region doped with first conductive impurities;
a first polysilicon layer doped with second conductive impurities and formed over the region doped with first conductive impurities;
a second polysilicon layer formed over the first polysilicon layer and doped with first conductive impurities;
an electric charge capture layer formed at both lateral sides of the first polysilicon layer; and
first and second control gates formed at lateral sides of the electric charge capture layer.

8. The apparatus of claim 7, wherein the electric charge capture layer comprises a first oxide layer, a nitride layer, and a second oxide layer.

9. The apparatus of claim 7, wherein the electric charge capture layer comprises one selected from the group consisting of SiO₂—Si₃N₄—SiO₂, SiO₂—Si₃N₄-Al₂O₃, SiO₂—Si₃N₄—Al₂O₃, and SiO₂—Si₃N₄—SiO₂—Si₃N₄—SiO₂.

10. The apparatus of claim 7, wherein the second polysilicon layer protrudes beyond the control gate.

11. The apparatus of claim 7, further comprising a protrusion formed over the region doped with the first conductive impurities, and the first polysilicon layer is formed over the protrusion.

12. The apparatus of claim 7, further comprising an insulating layer formed at both sides of the region doped with the first conductive impurities.

13. The apparatus of claim 7, wherein the electric charge capture layer is formed at both sides of the second polysilicon layer.

14. The apparatus of claim 7, wherein the electric charge capture layer is formed between the region doped with the first conductive impurities and the first and second gates.

15. The apparatus of claim 7, further comprising an insulating layer formed between the region doped with the first conductive impurities and the first and second gates.

16. A memory device comprising:
a source region;
a drain region;
a channel region formed between the source region and the drain region;
at least one electric charge capture layer adjacent to the channel region; and
at least one control gate adjacent to the electric charge capture layer,
wherein the source region, the channel region and the drain region are vertically aligned, and the channel region, the electric charge capture layer and the control gate are horizontally aligned.

17. The apparatus of claim 16, wherein at least some portions of the channel region, the electric charge capture layer and the control gate are aligned on a same horizontal plane.

18. The apparatus of claim 16, wherein the electric charge capture layer comprises a first oxide layer, a nitride layer and a second oxide layer, which are horizontally aligned.

19. The apparatus of claim 16, wherein the electric charge capture layer is formed at both sides of the first polysilicon layer.

20. The apparatus of claim 16, wherein the at least one electric charge capture layers comprises a plurality of electric charge capture layers that capture electric charges in the channel region, and the at least one control gate comprises a plurality of control gates to which control voltage is applied.
